(19) United States
(12) Patent Application Publication
(10) Pub. No.: US 2026/0354212 A1
(43) Pub. Date: Nov. 5, 2026

(54) METHODS OF FORMING A SURFACE-MOUNTED INTEGRATED CIRCUIT PACKAGE

(71) Applicants: NEXPERIA TECHNOLOGY (SHANGHAI) LTD., Shanghai (CN); NEXPERIA.B.V., Nijmegen (NL)

(72) Inventors: Yuan LI, Weihai (CN); DongBo ZHANG, Suzhou (CN)

(73) Assignees: NEXPERIA TECHNOLOGY (SHANGHAI) LTD., Shanghai (CN); NEXPERIA.B.V., Nijmegen (NL)

(21) Appl. No.: 19/722,341

(22) Filed: Jun. 26, 2026

Related U.S. Application Data
(63) Continuation of application No. PCT/CN2023/142016, filed on Dec. 26, 2023.

(51) Int. Cl. H10W 70/04; H10W 74/01

(52) U.S. Cl. CPC H10W 70/048; H10W 70/042; H10W 74/014

(57) ABSTRACT

A method of forming a plurality of surface-mounted integrated circuit packages is provided, including a substrate having a first and second surface, die pads, and contact pads associated with each die pad, that extend from the first surface. The distance between the first and second surfaces defines a first thickness of the substrate. The method includes mounting a die on each of the die pads, electrically connecting each die to the associated contact pads, encapsulating each die and its connected contact pads in a encapsulant, removing material from the second surface to reduce the thickness of the substrate, forming channels in the second surface, plating the second surface with a wettable material, including plating of the channels in the second surface, and cutting through the substrate and encapsulant via the channels in the second surface of the substrate.

### CROSS-REFERENCE TO RELATED APPLICATIONS

This application is a continuation of PCT/CN2023/142016 filed on Dec. 26, 2023, the contents of which are incorporated by reference herein in its entirety.

### BACKGROUND

### 1. Field of the Disclosure

The present disclosure relates to methods of forming surface mounted integrated circuit packages.

### 2. Description of the Related Art

When assembling a surface-mounted integrated circuit package to a circuit board or external circuitry, a robust and reliable electrical connection is required is required to ensure reliable performance of the circuitry.

Surface-mounted integrated circuit packages are commonly connected to circuit boards or external circuitry via soldering. Therefore, increasing the solderable (or wettable) area of the surface-mounted integrated circuit package assists in providing a robust and reliable electrical connection between the package and the circuit board upon which it is mounted, or the external circuit to which it is connected.

Traditionally, Dual Flat No Leads (DFN) and Quad Flat No Lead (QFN) surface-mounted integrated circuit packages have achieved this by increasing their wettable area by including wettable surfaces on both their underside and flanks/sides.

Using surface-mounted integrated circuit packages with wettable flanks also allows for more efficient manufacturing processes of electrical equipment. For example, in the automotive industry, Automated Visual Inspection (AVI) is the preferred method of inspecting assembled electrical circuitry. AVI can be easily carried out with surface-mounted integrated circuit packages with wettable flanks (such as DFN and QFN packages) once they have been connected to circuit boards or external circuitry, as the soldered connections can be easily seen and assessed. AVI is preferred as it is a more time efficient method of quality control than traditional X-ray inspection, which is required for inspection of soldered connections that cannot be seen externally (e.g. when a surface-mounted integrated circuit package is connected to a circuit board or external circuitry via its underside surface only).

Fast and reliable manufacture of surface-mounted integrated surface packages with side wettable flanks poses a number of challenges, such as providing packages with sufficient solderable areas on the flanks of the packages to provide robust and reliable electrical connections. For example traditional manufacturing processes may produce mould flash, which may also interfere with the reliability of the side wettable flank connections of the packages, and which may require additional manufacturing time to resolve.

### SUMMARY

An embodiment of the present disclosure provides a method of forming a plurality of surface-mounted integrated circuit packages. The method comprises providing a substrate comprising a first surface and a second surface, wherein a plurality of die pads, and a plurality of contact pads associated with each die pad, extend from the first surface, and wherein the distance between the first and second surfaces defines a first thickness of the substrate. The method further comprises: mounting a die on each of the die pads; electrically connecting each die to the associated contact pads of its die pad; encapsulating each die and its connected contact pads in a protective encapsulant; removing material from the second surface to reduce the thickness of the substrate to a second thickness; forming a plurality of channels in the second surface of the substrate; plating the second surface with a wettable material, including plating of the plurality of channels of the in the second surface; and, cutting through the substrate and protective encapsulant via the plurality of channels in the second surface of the substrate.

Assembly of a plurality of surface-mounted integrated circuit packages in this manner allows the packages to be formed with a single plating step while also minimising the cutting operations required to singulate the packages. This technique can be used to form both Dual Flat No Lead (DFN) packages, as well as Quad Flat No Lead (QFN) packages.

All of the packages formed comprise at least two side wettable flanks, arising from the channels being plated during the manufacture process, wherein the wettable areas of the sides are equal to (or close to equal to) the thickness of the substrate. This provides a large area for solder to be applied during connection to external circuitry (for example, connection to a circuit board), providing a robust and reliable connection between a surface-mounted integrated surface package and the external circuitry.

Such a technique may be particularly advantageous when assembling surface mounted integrated surface packages for use in manufacturing processes which implement automated visual inspection (AVI), negating the need for X-ray inspection techniques; as the side soldered connections can be easily seen and assessed.

The method can comprise forming each channel of the plurality of channels with a depth equal to or greater than the second thickness of the substrate. Alternatively, the method can comprise forming each channel of the plurality of channels with a depth less than the second thickness of the substrate. When plating the second surface of the substrate, the channels are also plated. As plating of the channels ultimately provides the wettable side flanks of the final surface-mounted integrated circuit packages, the depth of the channels may determine the height of the of the wettable areas on the flanks of each package. Therefore, the greater the channel depth, the greater solderable area that is available during connection of each package to external circuitry.

The method can comprise, following the step of forming the plurality of channels, deburring each of the plurality channels. Deburring of the channels may allow the process of plating (especially in the channels) to have improved consistency, with a consistent surface within channels for the plating to be applied. This can provide consistent side wettable flanks on all surface-mounted integrated circuit packages produced.

The method can comprise removing material from the second surface of the substrate via grinding.

The method can comprise, following the step of plating the second surface with a wettable material, forming a second plurality of channels in the second surface. The second plurality of channels can be at least equal to the second thickness of the substrate. The second plurality of channels can be formed between each die pad and its associated contact pads.

The method can comprise cutting through the substrate and protective encapsulant via the plurality of channels in the second surface of the substrate by chemical etching or plasma etching. Such etching techniques may be advantageous as they allow a high degree of precision when cutting and/or singulating assembled packages.

Alternatively, the method comprises cutting through the substrate and protective encapsulant via the plurality of channels in the second surface of the substrate by blade dicing or laser dicing. Blade dicing may be advantageous for use in cutting methods used in singulating multiple packages manufactured in a ‘grid’ pattern. Laser dicing may be an advantageous cutting technique given the high levels of precision that can be achieved, and minimal mechanical stress on the components of the assembled packages when cutting.

Alternatively, the method comprises cutting through the substrate and protective encapsulant via the plurality of channels in the second surface of the substrate by water jet cutting. The use of water jet cutting may be advantageous as this technique can be used to cut a wide variety of materials, while minimising stress on the assembled package.

Alternatively, the method comprises cutting through the substrate and protective encapsulant via the plurality of channels in the second surface of the substrate by sawing. Sawing may provide a fast and cost-effective cutting/singulating means.

The plurality of channels can be arranged to define the perimeter of each surface mounted integrated circuit package, wherein cutting the through the substrate and protective encapsulant via the plurality of channels in the second surface may singulate a plurality of Quad Flat No Lead (QFN) surface mounted integrated circuit packages.

Alternatively, following the step of cutting through the substrate and protective encapsulant via the plurality of channels in the second surface of the substrate, the method may comprise singulating a plurality of Dual Flat No Lead (DFN) surface-mounted integrated circuit packages.

### BRIEF DESCRIPTION OF THE DRAWINGS

Embodiments of the present disclosure will now be described with reference to the accompanying drawings, in which:

FIGS. 1A, 1B, 1C, 1D, 1E, 1F, 1G, 1H and 1I demonstrate a first method of forming one or more surface mountable integrated surface packages, according to the present disclosure.

FIGS. 2A and 2B demonstrate different channel arrays used during manufacture of surface mounted integrated circuit packages.

### DETAILED DESCRIPTION

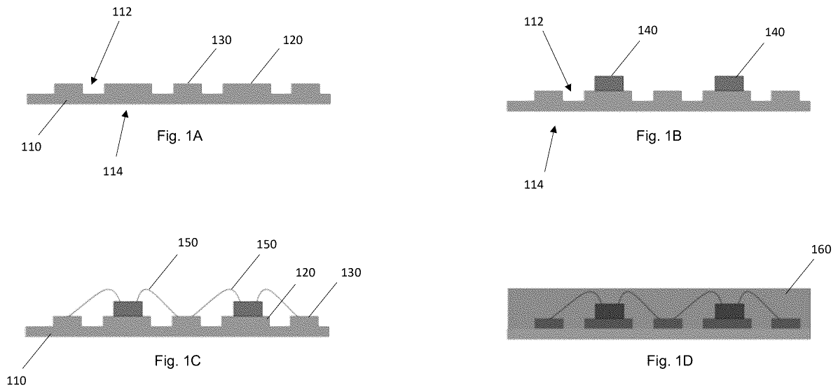

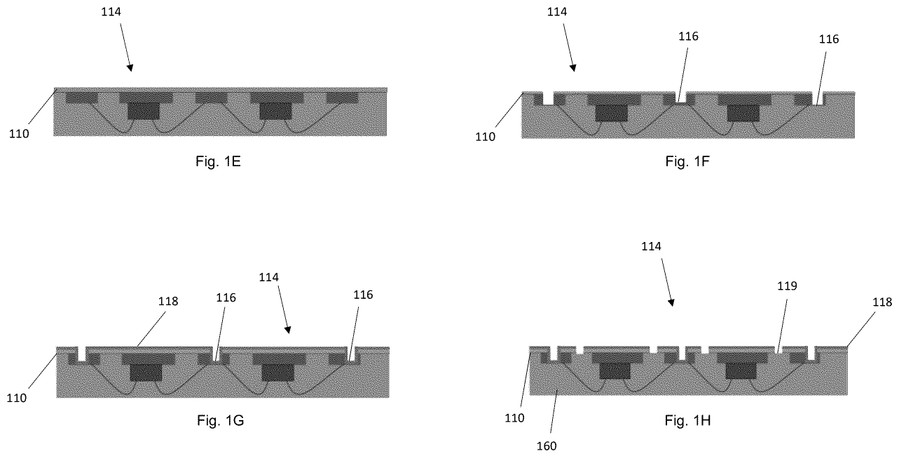

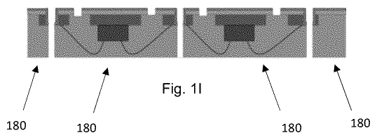

FIG. 1A shows the first step in a first method of manufacturing a plurality of surface-mounted integrated circuit, according to the present disclosure. Provided is a substrate 110 (or leadframe) comprising a first surface 112 and a second surface 114. The first surface 112 may alternatively be termed the ‘upper’ surface, and the second surface may be termed the ‘lower’surface.

A plurality of die pads 120 extend from the upper surface of the substrate 110. Each die pad 120 has a plurality of associated connection pads 130. In this example, the plurality of die pads 120 and plurality of connection pads 130 associated with each die pad 120 have been etched onto the first surface 112 of the substrate 110.

A first thickness is defined between the first surface 112 and the second surface 114. In this example, the first thickness is 100 μm, but this thickness can be varied dependent on the application. Additionally, the thickness of each of the plurality of die pads 112 and their associated connection pads 114 is 100 μm. A thickness of 100 μm for the die pads 112 and associated connection pads 114 may provide strong support when a die 140 (integrated circuit chip) is bonded to the die pad 112, or when connection wires 150 are bonded to each connection pad 114. This thickness can be varied dependent on the application.

In this example, the substrate 110 is formed of copper. In alternative examples, the substrate can be formed of any suitable metal within the understanding of one skilled in the art, such a copper alloy, iron-nickel alloy, aluminium, or gold-plated copper, for example. The metallic material may be selected dependent on the specific requirements of the surface-mounted integrated circuit package, including electrical performance, thermal management, mechanical strength, cost considerations, and the like.

FIGS. 1B and 1C show the step of bonding a die 140 (integrated circuit chip) to each of the die pads 120 of the substrate 110. In this example, a die 140 has been assembled to each die pad 120. Each die is then bonded to each of its associated contact pads 130 via wires 150 (i.e. via wire bonding).

In other examples, the die 140 may be bonded to the substrate using other techniques understood by one skilled in the art, such as flip-chip bonding, thermocompression bonding or eutectic bonding, for example.

FIG. 1D demonstrates the step of encapsulating the plurality of dies 140, their associated connection pads 130, and wire bonds 150 in a protective encapsulant 160. The protective encapsulant 160 shields each die 140, associated contact pads 130 and bond wires 150 from environmental factors such as moisture, dust and physical damage, while also providing additional structural support to each surface mounted integrated circuit packages. This protective encapsulant 160 can be formed by transfer moulding, wherein the substrate of FIG. 1C is positioned within a mould cavity and closed within a mould tool to allow the protective encapsulant to be applied. The mould may then be subjected to heat and pressure to cause the protective encapsulant 160 material to flow and fill the mould cavity, applying the protective encapsulant 160 material to the first surface 112, and fully encapsulating the plurality of dies 140, their associated contact pads 130 and the bond wires 150. The protective encapsulant 160 can then be cured to allow it to solidify, and then allowed to cool. The substrate 110, including the protective encapsulant 160 disposed upon its first surface 112, may then be withdrawn from the mould.

FIG. 1E demonstrates the method step of reducing the thickness of the substrate 110 form a first thickness to a second thickness (wherein the first and second thicknesses are defined between the first surface 112 and the second surface 114 of the substrate 110). In this example, the second thickness is produced by grinding or etching the second surface 114 to remove material. In the method of this example, the first thickness of the substrate 110 is 100 μm, and the second thickness is 50 μm, but in other examples the first and second thicknesses may vary in value; dependent on what characteristics are required from each integrated surface package.

FIG. 1F shows the subsequent method step of forming a plurality of channels 116 in the substrate 110. The channels 116 can be formed in the substrate via multiple different manufacturing techniques. For example, the channels 116 can be machined into the second surface 114 of the substrate 110 (by sawing, etching, plasma dicing or laser cutting). Alternatively the channels 116 can be chemically etched into the second surface 114 of the substrate 110. The plurality of channels 116 will define at least two edges of each surface mounted integrated circuit package, and will be used as guides in forming at least two flanks/sides of each individual surface-mounted integrated surface package (as will be described in greater detail below).

The depth of each of the plurality of channels 116 can be equal to the second thickness of the substrate 110. In other examples, the depth of the plurality of channels 116 may be greater than, or less than the second thickness of the substrate 110. The benefits of controlling the depth of the plurality of channels will be outlined in detail in the description of FIG. 1G, concerning the step of plating 118 the second surface of the substrate 110.

In this example, the plurality of channels 116 also extend into the plurality of contact pads 130 associated with each die pad 120, but this may not always be the case.

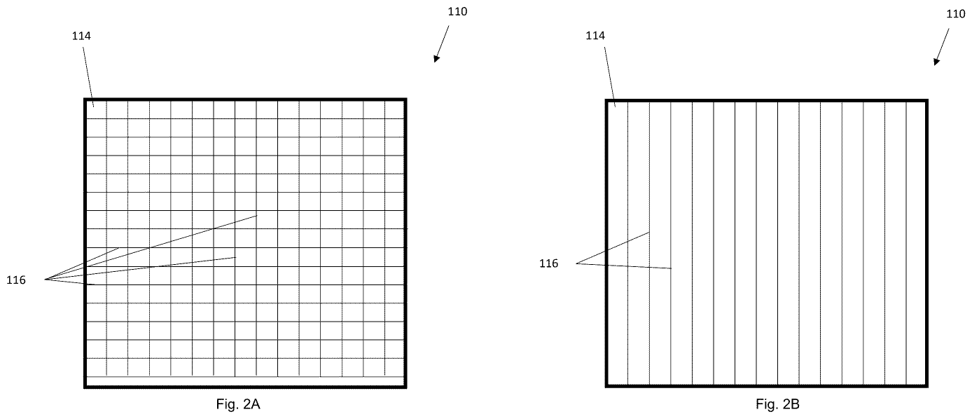

Further, the specific arrangement of the channels 116, and the benefits of each arrangement will be described in greater detail below, in the description of FIGS. 2A and 2B.

The method step shown in FIG. 1F can also include deburring each of the channels 116 to improve their surface finish/quality. Improving the surface finish/quality of the channels 116 may be helpful for subsequent manufacturing steps (such as when the channels are plated, FIG. 1G), and/or improving the overall quality and consistency of the finished surface-mounted integrated surface packages.

FIG. 1G demonstrates plating 118 of the second surface 114 of the substrate, wherein the second surface 114 is plated with a wettable material. The second surface can be plated with any suitable wettable material within the understanding of one skilled in the art, for example aluminium, stainless steel, polycarbonate or polypropylene, silicon, and the like.

Plating 118 is applied across the entire second surface 114 of the substrate. This will ultimately form the underside of each surface-mounted integrated surface package. Therefore, each package is provided with a wettable underside, helping to improve the reliability and robustness of the electrical connection with the circuit board or external circuitry to which the package is connected. The plating 118 also extends into the channels 116 of the substrate 110. As discussed in relation to FIG. 1F, the channels 116 may define, and can be used to form, at least two flanks/sides of each surface-mounted integrated circuit package in subsequent manufacture. Therefore, by also plating 118 the channels 116 during manufacture, a wettable surface will also be provided on at least two of the sides/flanks of each package. Therefore, varying the height of the channels during manufacture (as discussed within the method step of FIG. 1F) will determine the height that the wettable surface extends up a side/flank of each package. The greater the wettable surface extends up a side/flank of a package the greater the solderable/wettable area on at least one side of each produced package. Having a greater side solderable/wettable area will also improve electrical connection between the package and the circuit board or external circuitry to which the package is connected.

Having a solderable/wettable area on at least one of the sides/flanks of each package also allows for AVI to be performed when carrying out quality control electric circuits incorporating surface-mounted integrated circuit packages, negating the need for more time consuming inspection methods such as X-ray.

FIG. 1H demonstrates an optional method step of forming a second plurality of channels 119 in the second surface 114 of the substrate 110. The channels can be formed by one or more of the same methods used to form the first plurality of channels 116. As can be seen in FIG. 1H, the second plurality of channels extend far enough to disconnect the substrate 110 underneath each die pad 120 from the substrate underneath each die pad's 120 associated contact pads 130.

FIG. 1I shows singulation of individual surface mounted integrated circuit packages 180. As shown, singulation has occurred by cutting through substrate 110 and the protective encapsulant 160 via each of the channels 116 within the substrate 110. The substrate 110 has been divided so that each package includes a die 140 and its associated contact pads 130, within the protective encapsulant 160. The wettable plating 118 extends along the second surface of the substrate 110, and up at least two of the sides of each package 180—i.e. packages 180 with side wettable/solderable flanks have been formed, wherein the height of the solderable/wettable area on the sides of each package 180 is at least equal to the second thickness of the substrate 110.

FIGS. 2A and 2B demonstrate different channel arrays used during manufacture of surface mounted integrated circuit packages. Specifically, FIG. 2A represents a channel array that may be used in the manufacture of QFN packages, while FIG. 2B represents a channel array that may be used in the manufacture of DFN packages.

Within FIG. 2A, the second surface 114 of the substrate 110 of the above described examples is shown. Within this example, a plurality of channels 116 have been formed in the second surface 114. Said channels 116 are arranged parallel and perpendicular to one and other, creating a grid pattern, with the channels 116 marking the perimeter of each individual surface mounted integrated circuit package 180 (e.g., included within the perimeter is a die 140 upon a die pad 120, and its associated contact pads 130; none of which are shown).

Therefore, when plating of the second surface 114 is performed, the plating 118 will extend up all four sides of each package—providing packages wherein all four sides will comprise solderable/wettable areas. Arranging/forming the channels 116 in this manner may be used in the production of QFN packages.

Alternatively, the channel arrangement shown in FIG. 2B can be used in the manufacture of DFN packages, in accordance with the manufacture methods described above. As with FIG. 2A, the substrate is provided 110 with the second surface 114 of the substrate shown. In this example, the channels 116 are only formed substantially parallel to one and other. Therefore, the channels 116 will only outline two sides of each surface-mounted integrated circuit package 180. When the second surface 114 is plated, the plating 118 will extend into the channels 116. Therefore, when the cutting/diving operation via the channels is performed to start the process of singulating the packages, plating 118 will only be provided on two sides of each package. To finalise singulation of each package when this array of channels 116 is used, an additional method step of cutting through the substrate 110, 210 and protective encapsulant 160 (not shown), substantially perpendicular to the channels 116, will be required. Therefore, arranging/forming the channels 116 in this manner may be used in the production of DFN packages.

While specific embodiments of the disclosure have been described above, it will be appreciated that the disclosure can be practiced otherwise than as described. The descriptions above are intended to be illustrative, not limiting. Thus, it will be apparent to one skilled in the art that modifications can be made to the disclosure as described without departing from the scope of the claims set out below.

1. A method of forming a plurality of surface-mounted integrated circuit packages, the method comprising the steps of:
providing a substrate comprising a first surface and a second surface,
providing a plurality of die pads, and a plurality of contact pads associated with each die pad, extend from the first surface, wherein the distance between the first and second surfaces defines a first thickness of the substrate;
mounting a die on each of the die pads;
electrically connecting each die to the associated contact pads of the die pad;
encapsulating each die and its connected contact pads in a protective encapsulant;
removing material from the second surface to reduce the thickness of the substrate to a second thickness;
forming a plurality of channels in the second surface of the substrate;
plating the second surface with a wettable material, including plating of the plurality of channels of the in the second surface; and
cutting through the substrate and protective encapsulant via the plurality of channels in the second surface of the substrate.

2. The method of claim 1, further comprising forming each channel of the plurality of channels with a depth equal to or greater than the second thickness of the substrate.

3. The method of claim 1, further comprising forming each channel of the plurality of channels with a depth less than the second thickness of the substrate.

4. The method of claim 1, comprising deburring each of the plurality of channels following the step of forming the plurality of channels.

5. The method of claim 1, further comprising removing material from the second surface of the substrate via grinding.

6. The method of claim 1, further comprising forming a second plurality of channels in the second surface, following the step of plating the second surface with a wettable material.

7. The method of claim 6, wherein the second plurality of channels are at least equal to the second thickness of the substrate, and wherein the second plurality of channels are formed between each die pad and its associated contact pads.

8. The method of claim 1, wherein the step of cutting through the substrate and protective encapsulant via the plurality of channels in the second surface of the substrate is performed by chemical etching or plasma etching.

9. The method of claim 1, wherein the step of cutting through the substrate and protective encapsulant via the plurality of channels in the second surface of the substrate is performed by blade dicing or laser dicing.

10. The method of claim 1, wherein the step of cutting through the substrate and protective encapsulant via the plurality of channels in the second surface of the substrate is performed by water jet cutting.

11. The method of claim 1, wherein the step of cutting through the substrate and protective encapsulant via the plurality of channels in the second surface of the substrate is performed by sawing.

12. The method of claim 1, wherein the plurality of channels are arranged to define the perimeter of each surface mounted integrated circuit package, and wherein
cutting the through the substrate and protective encapsulant via the plurality of channels in the second surface singulates a plurality of Quad Flat No Lead (QFN) surface mounted integrated circuit packages.

13. The method of claim 1, following the step of cutting through the substrate and protective encapsulant via the plurality of channels in the second surface of the substrate, comprising singulating a plurality of Dual Flat No Lead (DFN) surface-mounted integrated circuit packages.

14. The method of claim 2, comprising deburring each of the plurality of channels following the step of forming the plurality of channels.

15. The method of claim 3, comprising deburring each of the plurality of channels following the step of forming the plurality of channels.

16. The method of claim 2, following the step of cutting through the substrate and protective encapsulant via the plurality of channels in the second surface of the substrate, comprising singulating a plurality of Dual Flat No Lead (DFN) surface-mounted integrated circuit packages.

17. The method of claim 3, following the step of cutting through the substrate and protective encapsulant via the plurality of channels in the second surface of the substrate, comprising singulating a plurality of Dual Flat No Lead (DFN) surface-mounted integrated circuit packages.

18. The method of claim 4, following the step of cutting through the substrate and protective encapsulant via the plurality of channels in the second surface of the substrate, comprising singulating a plurality of Dual Flat No Lead (DFN) surface-mounted integrated circuit packages.
